(19) United States
(12) Patent Application Publication
(10) Pub. No.: US 2021/0287833 A1
(43) Pub. Date: Sep. 16, 2021

(54) CO-BASED AMORPHOUS MAGNETIC THIN STRIP FOR MAGNETIC SENSOR, MAGNETIC SENSOR USING THE SAME, AND MANAGEMENT SYSTEM

(71) Applicants: KABUSHIKI KAISHA TOSHIBA, Tokyo (JP); TOSHIBA MATERIALS CO., LTD., Yokohama-shi (JP)

(72) Inventors: Tadao SAITO, Yokohama Kanagawa (JP); Takahiro MAEDA, Yokohama Kanagawa (JP); Satoru HABU, Yokohama Kanagawa (JP)

(73) Assignees: KABUSHIKI KAISHA TOSHIBA, Tokyo (JP); TOSHIBA MATERIALS CO., LTD., Yokohama-shi (JP)

(21) Appl. No.: 17/328,139

(22) Filed: May 24, 2021

Related U.S. Application Data
(63) Continuation of application No. PCT/JP2019/045608, filed on Nov. 21, 2019.

(30) Foreign Application Priority Data
Nov. 29, 2018 (JP) 2018-223335

(51) Int. Cl. H01F 1/153

(52) U.S. Cl. CPC H01F 1/15316; G07D 7/04

(57) ABSTRACT

A Co-based amorphous magnetic thin strip for a magnetic sensor is disclosed. The Co-based amorphous magnetic thin strip has a width W equal to or smaller than 1 mm, a length L between 6 mm and 100 mm inclusive, a ratio L/W between 20 and 1000 inclusive, a strip thickness t between 10 μm and 28 μm inclusive, and a cross section of a rectangle or a trapezoid.

### CROSS-REFERENCE TO RELATED APPLICATIONS

This application is a continuation of International Application No. PCT/JP2019/045608, filed on Nov. 21, 2019, which claims the benefit of priority of the prior Japanese Patent Application No. 2018-223335, filed on Nov. 29, 2018, the entire contents of which are incorporated herein by reference.

### FIELD

An embodiment described herein relates generally to a Co-based amorphous magnetic thin strip for a magnetic sensor, a magnetic sensor using the same, and a management system.

### BACKGROUND

In recent years, multifunction machines, which have both functions of printers and copiers, have been used. The multifunction machines are often used by being connected to networks. The spread of the multifunction machines makes it easy for information to be copied, printed, and stored in the networks.

This results in security management of secret information becoming important. It is necessary to prevent secret information from being taken out for other purposes or being copied. Security paper is used as one of options for the security management. Examples of the security paper include paper in which magnetic wires are embedded and paper on which special printing is made.

An example of the paper with the special printing is a bill. The paper with the special printing on its surface has an excellent forgery prevention effect. However, such paper with the special printing has a low security effect against theft, for example. Moreover, due to the necessity of making the special printing, a pattern is formed on the printed portion when white paper such as plain paper is used. In this case, when the printed portion is separated from the paper, the security function is lost. Furthermore, part of the paper, on which the pattern is formed, is unusable for normal white paper, so that the paper with the special printing is not necessarily convenient for use.

On the other hand, the paper with the magnetic wires have an antitheft effect because the magnetic wires can function as sensors. By cooperating with the multifunction machines, the paper with the magnetic wires can also be prevented from duplication for purposes other than the original purpose. Therefore, security paper in which the magnetic wires are embedded can have both functions of theft prevention and duplication prevention.

However, since the cross section of the wire has a curve, the positions of the wires may shift after they are scattered on paper. The occurrence of such a positional shift of the magnetic wires causes a problem of deterioration of flatness of paper due to the wires overlapping with each other. When the wires overlap with each other in white paper, a dark color comes out only at the overlapping portion. In this case, a problem may arise in that the position where the sensors have been embedded is found.

As described above, the conventional security paper has a problem in that the magnetic wires may overlap with each other in the security paper.

### BRIEF DESCRIPTION OF THE DRAWINGS

FIG. 1 is an external view exemplarily illustrating a Co-based amorphous magnetic thin strip for a magnetic sensor according to an embodiment;

FIG. 2 is a diagram exemplarily illustrating a shape of the Co-based amorphous magnetic thin strip for a magnetic sensor according to the embodiment when viewed from a top surface thereof;

FIG. 3 is a diagram exemplarily illustrating a shape of the Co-based amorphous magnetic thin strip for a magnetic sensor according to the embodiment when viewed from a side surface thereof;

FIG. 4 is an explanatory view of a strip thickness according to the embodiment;

FIG. 5 is a diagram exemplarily illustrating a magnetic sensor including the Co-based amorphous magnetic thin strips for a magnetic sensor according to the embodiment;

FIG. 6 is another diagram exemplarily illustrating the magnetic sensor including the Co-based amorphous magnetic thin strips for a magnetic sensor according to the embodiment; and

FIG. 7 is a diagram exemplarily illustrating a management system according to the embodiment.

### DETAILED DESCRIPTION

A Co-based amorphous magnetic thin strip for a magnetic sensor according to an embodiment includes a Co-based amorphous magnetic thin strip that may have a cross section of a rectangle or a trapezoidal, a width W equal to or smaller than 1 mm, a length L between 6 mm and 100 mm inclusive, a ratio L/W between 20 and 1000 inclusive, and a strip thickness t between 10 μm and 28 μm inclusive.

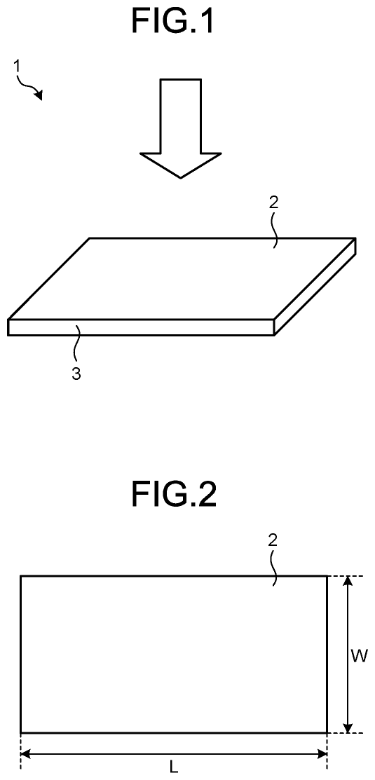

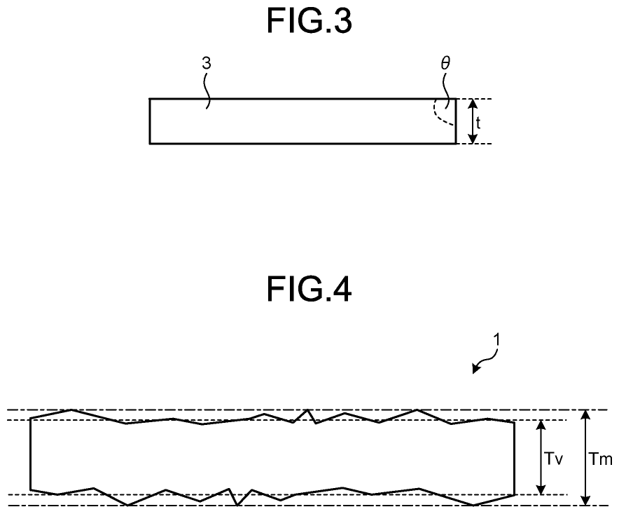

The Co-based amorphous magnetic thin strip for a magnetic sensor according to the embodiment is exemplarily illustrated in FIGS. 1 to 3. FIG. 1 is an external view. FIG. 2 is a top view. FIG. 3 is a side view. In FIGS. 1 to 3, a reference numeral “1” denotes a Co-based amorphous magnetic thin strip for a magnetic sensor, a reference numeral “2” denotes a top surface of the Co-based amorphous magnetic thin strip, a reference numeral “3” denotes a side surface of the Co-based amorphous magnetic thin strip, and “W” denotes a width of the Co-based amorphous magnetic thin strip. In FIGS. 1 to 3, “L” denotes a length of the Co-based amorphous magnetic thin strip, “t” denotes a strip thickness of the Co-based amorphous magnetic thin strip, and “0” denotes an angle of each of the four corners of the cross section of the Co-based amorphous magnetic thin strip.

The term Co-based amorphous refers to an amorphous alloy that contains the most cobalt (Co) as a constituent element. The Co-based amorphous alloy thin strip is excellent in magnetic properties. The magnetic sensor including the Co-based amorphous magnetic thin strip for a magnetic sensor has high sensibility required for magnetic sensors. Examples of the magnetic alloy include an Fe-based amorphous alloy and an Fe-based fine crystal alloy. The Fe-based magnetic alloy contains the most Fe (iron) as a constituent element. The Co-based amorphous alloy, which is the constituent material of the Co-based amorphous magnetic thin strip according to the present embodiment, has higher corrosion resistance than that of the Fe-based magnetic alloy. The Co-based amorphous alloy is generally rustproof. The Co-based amorphous alloy makes it possible to obtain security paper being durable.

In the following description, the Co-based amorphous magnetic thin strip for a magnetic sensor may be simply referred to as a magnetic thin strip.

The magnetic thin strip has the width W equal to or smaller than 1 mm, the length L between 6 mm and 100 mm inclusive, the ratio L/W between 20 and 1000 inclusive, and the strip thickness t between 10 μm and 28 μm inclusive. The ratio L/W refers to a ratio of the length L to the width W of the magnetic thin strip. Differences between the width W, the length L, and the strip thickness t are expressed by t<W<L.

The shape of the magnetic thin strip when viewed from above is polygonal. FIG. 2 illustrates an example where the shape is a rectangle when viewed from above. The short side of the rectangle is the width W whereas the long side thereof is the length L. The arrow direction in FIG. 1 is the viewing direction when viewed from above.

The width W is equal to or smaller than 1 mm. If the width W is larger than 1 mm, the location of the magnetic thin strip embedded in white paper is easily found. The lower limit value of the width W is preferably equal to or larger than 0.05 mm. If the width W is smaller than 0.05 mm (that is, smaller than 50 μm), the possibility of the magnetic thin strip being broken becomes higher. Therefore, the width W is preferably between 0.05 mm and 1 mm inclusive, more preferably between 0.1 mm and 0.3 mm inclusive.

The length L is between 6 mm and 100 mm inclusive. If the length L is smaller than 6 mm, the reception sensitivity required for the sensor deteriorates. If the length L is larger than 100 mm, the possibility of the magnetic thin strip being twisted becomes higher. In a case that the magnetic thin strip is twisted, there is a difficulty to maintain the flatness of paper. Therefore, the length L is preferably between 6 mm and 100 mm inclusive, more preferably equal to or smaller than 55 mm.

The L/W ratio is between 20 and 1000 inclusive. If the L/W ratio is smaller than 20, the reception sensitivity deteriorates. If the L/W ratio is larger than 1000, the length L is so long that the possibility of the magnetic thin strip being twisted becomes higher in a process of embedding the magnetic thin strip in paper. Therefore, the L/W ratio of the magnetic thin strip is preferably between 20 and 1000 inclusive, more preferably between 100 and 500 inclusive. The L/W ratio in such a range can satisfy enhancement of both reception sensitivity and handling property.

The strip thickness t is between 10 μm and 28 μm inclusive. The magnetic thin strip is made by a roll rapid cooling method, which is described later. The thickness of the magnetic thin strip made by the roll rapid cooling method can be used without any changes to satisfy the strip thickness tin the range between 10 μm and 28 μm inclusive. Thus, mass productivity can be enhanced.

Note that the strip thickness t is the thickness of the magnetic thin strip, and is represented by an average strip thickness Tv exemplified in FIG. 4. FIG. 4 illustrates an exemplary schematic diagram of an enlarged cross section of the magnetic thin strip magnified 2000 times by a scanning electron microscope (SEM). As illustrated in FIG. 4, the actual surface of the magnetic thin strip is uneven. The strip thickness measured by a micrometer indicates a maximum value Tm of the thickness of the magnetic thin strip. The average strip thickness Tv is calculated from a density of a constituent material of the magnetic thin strip having a unit length and a unit width based on measurement of a mass of the constituent material having the unit length and the unit width. The unit length and the unit width described herein refer to the length and the width of a single piece of the magnetic thin strip. The unit length and the unit width may be the length and width of two or more magnetic thin strips.

As for the density of the constituent material of the magnetic thin strip, a known density value of the constituent material may be used, or a density obtained through the Archimedes method may be used. The width W of the magnetic thin strip is measured. The volume of the magnetic thin strip per length of 1 m is obtained by (length L)×(width W)×(thickness t). The volume is obtained by dividing the mass by the density. The strip thickness t, which is the average strip thickness Tv, can be calculated based on the parameters and the equations described above.

The smaller the unevenness of the magnetic thin strip surface is, the smoother the magnetic thin strip surface is. In this case, the ratio of the maximum value Tm to the average strip thickness Tv (Tm/Tv) in FIG. 4 becomes closer to a value of 1. On the other hand, the larger this ratio (Tm/Tv) is, the rougher the surface is.

The ratio W/t, which is the ratio of the width W to the strip thickness t, is preferably between 3 and 20 inclusive. The ratio W/t is more preferably between 5 and 12 inclusive. Adjusting the ratio W/t makes it easy to differentiate the width direction and the thickness direction of the magnetic thin strip from each other. This makes it possible to prevent occurrence of unevenness in the thickness direction of the paper when the magnetic thin strips are sprinkled on paper. The sprinkling of the magnetic thin strips on paper means at least one of integration of the magnetic thin strips with the paper, kneading of the magnetic thin strips into the paper, and sandwiching of the magnetic thin strips with the paper. When the unevenness on the paper surface occurs, a nib is caught by the paper surface, making it easy to occur problems such as a hole being made in the paper and the paper being broken. The cross-sectional shape of the magnetic thin strip is a rectangle or a trapezoid.

The magnetic thin strips having the cross-sectional shape of a rectangle or a trapezoid can prevent overlapping of the magnetic thin strips when being included in paper. The rectangle cross-sectional shape refers to a shape whose angle θ of each of the four corners is within a range of 90°±5° when viewed from the section perpendicular to the length L direction of the magnetic thin strip. The trapezoidal cross-sectional shape refers to a shape whose side surfaces are slopes. When the cross-sectional shape is a trapezoid, the angle of the slope is preferably equal to or larger than 50°. If the angle is smaller than 50°, an effect of preventing the overlapping of the magnetic thin strips is small.

For measuring the angle, an enlarged photograph of the cross section of the magnetic thin strip is used. The cross section is magnified 200 times by an optical microscope. The vertexes of the four corners may have a slightly R shape.

The magnetic thin strip in the embodiment preferably satisfies the following general formula.

(Co_{1-a-b}FeₐM_{b})₁₀₀₋ₓ(Si_{1-c}B_{c})ₓ General formula:

In the general formula above, M indicates one or more elements selected from titanium (Ti), vanadium (V), chromium (Cr), manganese (Mn), nickel (Ni), copper (Cu), zirconium (Zr), niobium (Nb), molybdenum (Mo), hafnium (Hf), tantalum (Ta), and tungsten (W).

In the general formula, a, b, c, and x are in the following ranges. The unit of the value of x is atomic percentage.

0.02≤a≤0.10

0≤b≤0.20

0.2≤c≤1.0

10≤x≤40

In the general formula, Fe (iron) can make a magnetostriction constant nearly zero depending on a ratio in relation to the Co (cobalt). Corrosion resistance can be enhanced by using the Co as a dominant component. As a result, the magnetic thin strip can be achieved that prevents deterioration of magnetic properties and hardly deteriorates with elapse of time. In the general formula described above, the value of “a” is between 0.02 and 0.10 inclusive, preferably between 0.03 and 0.08 inclusive.

As described above, the magnetic thin strip in the embodiment is a thin strip of the Co-based amorphous alloy that contains the most Co. The values of a, b, c, and x in the general formula can take any values in the corresponding ranges described above under the condition that Co is contained in largest quantity.

The element M improves soft magnetic properties. As described above, the element M is at least one or more elements selected from Ti, V, Cr, Mn, Ni, Cu, Zr, Nb, Mo, Hf, Ta, and W. These elements are effective for controlling the Curie temperature, for example. The element M is preferably one or two or more selected from Cr, Zr, and Nb. These elements can enhance not only the magnetic properties but also flexibility of the magnetic thin strip. The value of “b”, which indicates the content of the element M, is equal to or smaller than 0.20. When the element M is contained, the value of b is preferably equal to or larger than 0.01. If the value of b is smaller than 0.01, the effect of content of the element M is small. Therefore, the value of b is preferably between 0.01 and 0.20 inclusive, more preferably between 0.05 and 0.15 inclusive.

In the general formula, Si (silicon) and B (boron) are essential elements for amorphization. The value of “x”, which indicates a total content of Si and B, is between 10 atom % and 40 atom % inclusive, as described above. If the value of x is smaller than 10 atom %, amorphization is hard to achieve. If the value of x is larger than 40 atom %, the Curie temperature becomes too low. It is preferable for the magnetic thin strip to contain the both of Si (silicon) and B (boron). When the both are contained, the value of “c” is preferably between 0.2 and 0.9 inclusive. The magnetic thin strip containing the both Si and B can obtain effects of iron loss reduction and thermal stability improvement, for example.

It is preferably for the magnetic thin strip not to be damaged when being bent 180°. The 180° bending is performed such that the magnetic thin strip is bent (or folded) in half such as a mountain fold in paper folding. The magnetic thin strip that is not damaged when being folded in half makes it possible for paper including the magnetic thin strips to be folded in half. Convenience of the paper including the magnetic thin strips is increased. When paper is folded in half, a mountain fold is made in such a degree that a crease is made. When folding the magnetic thin strip in half before being built in paper, the magnetic thin strip is bent at the center of the length L thereof. When paper including the magnetic thin strips is bent, bending may be performed at an optional position of the paper. A bend test can be performed in compliance with, for example, JIS-Z-2248 of Japanese Industrial Standards (JIS).

Elasticity of the magnetic thin strip can be reduced by controlling the sizes of the width W, the length L, the strip thickness t, and the cross-sectional shape. If the elasticity is too strong, the magnetic thin strip may break through paper in a case where the paper is folded in half. For example, when the cross section has a semi-elliptic shape, such as that of a magnetic alloy fiber, the elasticity changes depending on the bending direction. The semi-elliptic shape is called a semi-cylindrical shape in sometimes. When the bending direction is the direction causing the elasticity to be increased, the magnetic alloy fibers may break through paper.

The magnetic thin strip contains Cr, Nb, and Zr as the element M and the shape of the magnetic thin strip is controlled, thereby making it possible for the magnetic thin strip to have both bending property and elasticity.

Heat treatment may be performed on the magnetic thin strip. Although the heat treatment is not essential, the magnetic properties of the magnetic thin strip are enhanced by performing the heat treatment. For example, the magnetic thin strip after being subjected to the heat treatment can have a coercive force of about 10 A/m. On the other hand, the strength of the magnetic thin strip reduces due to the heat treatment, so that such a magnetic thin strip is easily damaged when being bent 180°. Therefore, it is preferable that no heat treatment is performed when the magnetic thin strip is required to maintain the strength.

An insulation layer may be provided on the surface of the magnetic thin strip. The insulation layer can prevent the magnetic thin strip from rusting. Examples of the insulation layer include an insulation resin film and an oxide film. The Co-based amorphous alloy has a higher corrosion resistance than that of the Fe-based amorphous alloy. The Co-based amorphous alloy, however, rusts after more than 10 years. When the magnetic thin strip is used for security paper that needs long-term storage, the insulation layer is preferably provided on the surface of the magnetic thin strip. The insulation layer is preferably a transparent insulation resin. The transparent insulation resin does not cause a change in color even when the magnetic thin strips are sprinkled on white paper.

The magnetic thin strip described above can be applied to a magnetic sensor including magnetic thin strips. The magnetic sensor is an object including magnetic thin strips. Examples of the object including magnetic thin strips include paper, tags, and pens. The object is not limited to the examples. In the embodiment, the object serving as the magnetic sensor is paper. Paper including magnetic thin strips may be called security paper.

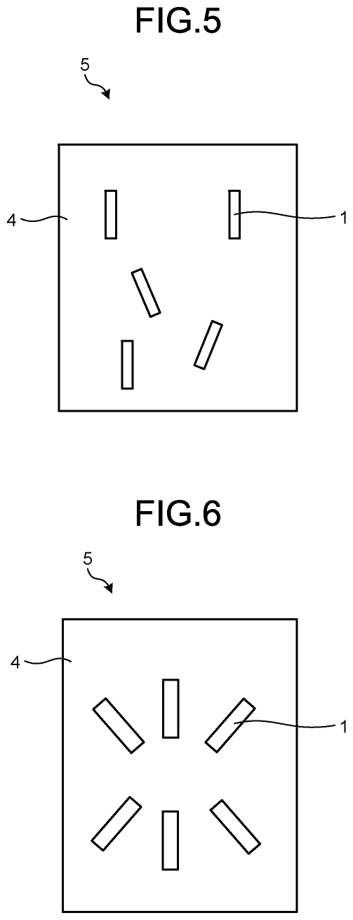

FIG. 5 illustrates an example of paper according to the embodiment. In FIG. 5, a numeral “1” denotes the magnetic thin strip, a numeral “4” denotes a paper body, and a numeral “5” denotes the paper including the magnetic thin strips 1. The paper including the magnetic thin strips is called security paper in sometimes.

The security paper refers to paper that needs crime prevention management such as theft prevention, forgery prevention, and number management. Examples of the security paper include copies of securities, contracts, and confidential information.

The magnetic thin strips 1 may be attached to the surface of the paper body 4 or embedded inside the paper body 4. When the magnetic thin strips 1 are embedded inside the paper body 4, the magnetic thin strips 1 are sandwiched between two paper bodies 4 to form a piece of paper. Since the sizes and shapes of the magnetic thin strips 1 according to the embodiment are controlled (or adjusted), the magnetic thin strips 1 hardly overlap with each other when being embedded inside the paper body 4. As a result, flatness of paper can be maintained. The overlapping of the magnetic thin strips 1 can be reduced in this way, thereby causing the positions of the magnetic thin strips 1 to be hardly pinpointed even when the magnetic thin strips 1 are applied to white paper. From this point of view, a crime prevention effect is enhanced.

The number of the magnetic thin strips used for the security paper may be equal to or larger than one. The number of the magnetic thin strips used for the security paper, which will be described below, is preferable for the purpose of enhancing a sensor function.

The magnetic sensor as paper preferably includes the magnetic thin strips between 3 pieces and 2500 pieces inclusive per paper area of 62370 mm² (corresponding to an A4 size). The A4 size paper is 297 mm in length and 210 mm in width, so that it has an area of 62370 mm².

In the present embodiment, the A4 size is used as a reference. When using another size of paper, the preferable number of the magnetic thin strips is changed on the basis of an area ratio to the A4 size. For example, an A3 size paper is 420 mm in length and 297 mm in width, so that it has an area of 124740 mm². Since the area ratio between the A3 size and the A4 size is expressed by 124740 mm²/62370 mm², which is equal to 2, the preferable range of the number of the magnetic thin strips for the magnetic sensor using the A3 size paper is between 4 and 5000 inclusive.

For the multiple magnetic thin strips included in the magnetic sensor, it is also preferable that the Co-based amorphous magnetic thin strips for a magnetic sensor be randomly arranged. The random arrangement makes it hard to pinpoint where the Co-based amorphous magnetic thin strips are embedded, thereby making it possible to increase crime prevention effect.

The random arrangement refers to a state where the magnetic thin strips are distributed uniformly over paper. The state where the magnetic thin strips are distributed uniformly over paper means that, when paper is divided into a plurality of regions having a predetermined size and range, the quantity or the number of the magnetic thin strips included in each region is nearly the same. The fact that the quantity or the number of the magnetic thin strips is nearly the same means that the quantity or the number of the magnetic thin strips is the same in a range of ±10%. For example, in a case where paper is the A4 size, the number of the magnetic thin strips is preferably nearly the same in each of four equal parts of the paper.

In a case that the magnetic thin strips are distributed in an array manner at a specific position on paper, the portion around the specific position can be cut out of the paper one time and taken out. For example, it is assumed that there are five pieces of security paper and the magnetic thin strips are arranged only at a right corner region of each of the five pieces of paper. In this case, when the right corner region of the paper is cut off, the paper includes no magnetic thin strips. As a result, the security of the paper deteriorates. Therefore, the magnetic thin strips randomly arranged over paper can prevent deterioration of the security due to cut off, thereby enhancing security performance such as theft prevention.

Moreover, the magnetic thin strips distributed on paper are preferably arranged such that the length L directions of at least some of the magnetic thin strips differ from one another. The magnetic thin strips are more preferably radially arranged on paper. As illustrated in FIG. 6, the radial arrangement means a shape of the arrangement where the length L directions of at least some of the magnetic thin strips differ from one another, and the magnetic thin strips are arranged to be spread in all directions from a specific position serving as the spreading center in the paper. The center may coincide or may not coincide with the central position of the paper. The extending straight lines extending in the length directions of the magnetic thin strips with a radial shape is not limited to being intersected at one point, but may be intersected at a plurality of points. That is, the center of the radial shape formed by the magnetic thin strips is not limited to one concentrated point. A plurality of groups of the magnetic thin strips radially arranged may be arranged on a piece of paper.

The radial arrangement of the magnetic thin strips increases a reception sensitivity of a management system on the magnetic sensor being paper. The management system is described later. This is because the radial arrangement makes it easy to receive radio waves from any direction.

When the length L of the magnetic thin strip is larger than 25 mm, the number of the magnetic thin strips included in paper is preferably equal to or smaller than 50 per paper area of 62370 mm² (corresponding to the A4 size). The length L of the magnetic thin strip being larger than 25 mm enables the reception sensitivity to be enhanced. When the length L of the magnetic thin strip is larger than 25 mm, the number of the magnetic thin strips included in paper is preferably between 3 and 50 inclusive, more preferably between 3 and 20 inclusive per paper area of 62370 mm² (corresponding to the A4 size). When the number of the magnetic thin strips included in paper is equal to or smaller than 50, those magnetic thin strips are preferably radially arranged.

When the length L of the magnetic thin strip is smaller than 25 mm, the number of the magnetic thin strips included in paper is larger than 50 per paper area of 62370 mm² (corresponding to the A4 size). As the length L of the magnetic thin strip is shortened, the reception sensitivity deteriorates. When the length L of the magnetic thin strip is smaller than 25 mm, the number of the magnetic thin strips included in paper is preferably between 50 and 2500 inclusive per paper area of 62370 mm² (corresponding to the A4 size).

Both the magnetic thin strips having a length L equal to or larger than 25 mm and the magnetic thin strips having a length L of smaller than 25 mm may be used. When the number of larger magnetic thin strips (the length L is equal to or larger than 25 mm) is equal to or larger than 3, the magnetic thin strips are preferably radially arranged as described above.

A type of paper (the paper body 4 in FIG. 5) used for the security paper is preferably one selected from plain paper, high quality paper, and recycled paper. Plain paper is the genetic name of paper used for copying and printing. Plain paper is also called plain paper copier (PPC) paper. Plain paper is distinguished from thermal paper. Plain paper is suitable for crime prevention management when classified information is printed thereon. High quality paper is manufactured from 100% chemical pulp. Recycled paper is manufactured from a mixture of chemical pulp and recycled pulp.

Color of paper is preferably white. The white paper refers to paper having a brightness equal to or larger than 70%. The brightness is measured in compliance with, for example, JIS-P-8148 of Japanese Industrial Standards (JIS). The brightness is measured by the method (ISO brightness R₄₅₇) that a reflected light amount is digitized when a paper surface is irradiated with light.

In general, recycled paper has a brightness between 65% and 75% inclusive. Plain paper and high quality paper have a brightness equal to or larger than 80%. The magnetic thin strips according to the embodiment can prevent overlapping of the magnetic thin strips in a piece of paper, thereby making it possible to prevent reduction of brightness of paper.

The paper according to the embodiment can keep the brightness equal to or larger than 70% although the magnetic thin strips are embedded therein. This is a level at which the positions of the magnetic thin strips are not pinpointed unless paper is carefully observed while the paper is seen with sun light passing through the paper. The positions of the magnetic thin strips, thus, cannot be pinpointed under typical interior illuminating light. As a result, the crime prevention effect can be increased. White plain paper is most preferably used.

The paper including the magnetic thin strips as described above is preferable for various management systems. The management system preferably includes gates that perform transmission and reception.

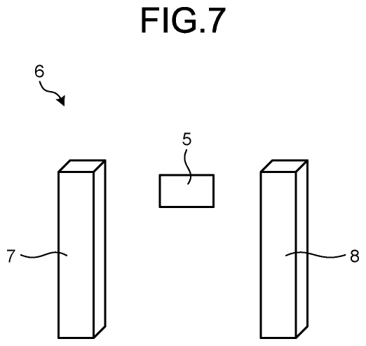

FIG. 7 exemplarily illustrates a management system according to the embodiment. In FIG. 7, a numeral “5” denotes the security paper including the magnetic thin strips, a numeral “6” denotes the management system, a numeral “7” denotes the gate that performs transmission, and a numeral “8” denotes the gate that performs reception.

The management system 6 has a pair of gates that transmit and receive radio waves. Specifically, the management system 6 has the gate 7 for transmitting radio waves and the gate 8 for receiving radio waves. The gate 7 transmits radio waves and the gate 8 receives the radio waves. When the security paper 5 passes through between the gates 7 and 8, a change occurs in a reception signal of the radio waves received by the gate 8. The change shows that the security paper 5 passes through between the gates.

Specifically, the gate 7 is provided with an excitation coil, for example. The gate 8 is provided with a detection coil. The excitation coil and the detection coil are arranged to face each other across the security paper passing through between the gates 7 and 8. It is assumed that an alternating excitation magnetic field having a predetermined intensity is applied to the excitation coil, and the security paper 5 passes through between the gates 7 and 8. In this case, extremely steep magnetization reversal occurs in the detection coil of the gate 8, for example. By detecting a change in the reception signal of the radio waves due to the magnetization reversal, it can be detected that the security paper 5 passes through between the gates.

The management system 6 is installed at, for example, an entrance of a shop to obtain a theft prevention effect. The management system 6 is installed on a safe or a classified document storage shelf to obtain the theft prevention effect. When the management system 6 is applied to a multifunction machine or the like, the management system 6 is effective for number management of security paper. The management system 6 is also effective for management against illegal copy, for example. The gate 8 is called a theft prevention gate in sometimes because of the theft prevention effect by the gate 8.

The management system utilizing the transmission-reception function uses radio waves having a frequency between 1 kHz and 200 kHz inclusive. The magnetic thin strip according to the embodiment is excellent in reception sensitivity for a frequency between 1 kHz and 200 kHz inclusive. The reception sensitivity can be increased although the number of the magnetic thin strips is small. The frequency of radio waves used by the management system according to the embodiment may be a frequency other than the range between 1 kHz and 200 kHz inclusive.

The following describes a manufacturing method of the magnetic thin strip according to the embodiment. The manufacturing method of the magnetic thin strip according to the embodiment is not limited to a specific method as long as the magnetic thin strip has the structure described above. The following method is a method with a better yield.

A process is performed that manufactures a long magnetic thin strip using a roll rapid cooling method. Any of known roll rapid cooling methods can be applied. A molten alloy serving as a mother alloy of the Co-based amorphous alloy is prepared. The molten alloy preferably satisfies the general formula described above.

The molten alloy is supplied onto a cooling roll rotating at a high speed from an injection nozzle, thereby making it possible to make a long magnetic thin strip. The use of the injection nozzle having a rectangle shape enables the magnetic thin strip to have a rectangle cross section. The strip thickness t can be also adjusted. The strip thickness of the long magnetic thin strip is preferably adjusted to the strip thickness t.

Next, the long magnetic thin strip is cut to adjust the length L and the width W of the magnetic thin strip. The cutting process is preferably performed such that the width direction of the long magnetic thin strip becomes the direction of the length L of the magnetic thin strip. The width of the long magnetic thin strip is preferably adjusted to be the same as the length L of the magnetic thin strip. The width of the long magnetic thin strip becomes the same as the length L of the magnetic thin strip by adjusting the long side of the injection nozzle to the length L of the magnetic thin strip.

For storage, the long magnetic thin strip is wound in a roll form in the lengthwise direction. If the cutting is performed such that the lengthwise direction becomes the length L direction of the magnetic thin strip, the magnetic thin strip after the cutting is easily warped. When a warp occurs, a process to eliminate the warp needs is required. The warp after the cutting is called a kickback. When the cutting is performed in the width direction of the long magnetic thin strip, a straight magnetic thin strip can be obtained due to a weak kickback. The cutting is performed in the direction causing a weak kickback, so that the magnetic thin strip can be obtained that has a rectangle cross section. After the completion of the process, the magnetic thin strip in the embodiment is obtained.

The insulation layer is provided on a surface of the magnetic thin strip as needed. The insulation layer is an oxide layer or a resin layer.

The following describes a manufacturing method of paper including the magnetic thin strips. Examples of a method for providing the magnetic thin strips include a method of attaching the magnetic thin strips to a surface of paper and a method of embedding the magnetic thin strips inside paper.

When the magnetic thin strips are attached to a surface of paper, an adhesive or the like may be used.

When the magnetic thin strips are embedded inside paper, the magnetic thin strips are sandwiched between two pieces of paper to be formed as a piece of paper. The cross section of the magnetic thin strip according to the embodiment is a rectangle. This makes it hard for the magnetic thin strips to overlap with each other when the magnetic thin strips are arranged on paper. The magnetic thin strip according to the embodiment has a given length L, a given width W, and a given thickness t, so that there is no need to change in color of paper. For example, white paper having a brightness equal to or larger than 70% can be obtained. The number of the magnetic thin strips included in paper is preferably the number described above.

### EXAMPLES

### Examples 1 to 10 and Comparative Examples 1 to 4

As examples and comparative examples, the magnetic thin strips and the comparative magnetic thin strips listed in Table 1 (described later) were prepared.

In Table 1, examples 1 to 10 and a comparative example 3 each represent that long magnetic thin strips were manufactured using a roll rapid cooling method and thereafter they were subjected to a cutting process. Examples 1 to 6 and examples 9 and 10 each represent that the cutting process was performed on the long magnetic thin strip to adjust the width to the corresponding length L.

An example 7 and comparative examples 2 and 3 each represent that the cutting process was performed on the long magnetic thin strip to adjust the length to the corresponding length L. In an example 8, the magnetic thin strip of the example 1 was subjected to heat treatment. The heat treatment was performed for 1 hour with a heat treatment temperature approximately 100° C. lower than the crystallization temperature of the magnetic thin strip.

In the examples 1 to 4, the examples 6 to 10, and the comparative examples 2 and 4, the cross section of the corresponding magnetic thin strip was a rectangle. Checking the cross section by using a metal microscope of 200 magnifications, each angle of the rectangle cross section was a range of 90°±5°. In the example 5, the angle of a trapezoidal cross section of the magnetic thin strip was equal to or larger than 60°.

The comparative magnetic thin strip in the comparative example 1 is an Fe-based amorphous alloy wire having a diameter of 30 μm. The cross-sectional shape of the comparative magnetic thin strip in the comparative example 1 was a circle. The cross-sectional shape of the comparative magnetic thin strip in the comparative example 3 was a semi-elliptic shape.

TABLE 1

| | | | | | | | Cross- |
|---|---|---|---|---|---|---|---|
| | Composition | L | W | | t | | sectional |
| | (atom %) | (mm) | (mm) | L/W | (μm) | W/t | shape |
| Example 1 | (Co_{0.90}Fe_{0.05}Cr_{0.05})₇₅ | 33 | 0.2 | 165 | 20 | 10 | Rectangle |
| | (Si_{0.5}B_{0.5})₂₅ | | | | | | |
| Example 2 | (Co_{0.90}Fe_{0.05}Cr_{0.05})₇₅ | 50 | 0.2 | 250 | 18 | 11 | Rectangle |
| | (Si_{0.5}B_{0.5})₂₅ | | | | | | |
| Example 3 | (Co_{0.90}Fe_{0.05}Cr_{0.05})₇₅ | 33 | 0.1 | 330 | 17 | 6 | Rectangle |
| | (Si_{0.5}B_{0.5})₂₅ | | | | | | |
| Example 4 | (Co_{0.90}Fe_{0.05}Cr_{0.05})₇₅ | 50 | 0.1 | 500 | 20 | 5 | Rectangle |
| | (Si_{0.5}B_{0.5})₂₅ | | | | | | |
| Example 5 | (Co_{0.90}Fe_{0.05}Cr_{0.05})₇₅ | 10 | 0.2 | 50 | 20 | 10 | Trapezoid |
| | (Si_{0.5}B_{0.5})₂₅ | | | | | | |
| Example 6 | (Co_{0.90}Fe_{0.05}Cr_{0.05})₇₅ | 20 | 0.1 | 200 | 22 | 5 | Rectangle |
| | (Si_{0.5}B_{0.5})₂₅ | | | | | | |
| Example 7 | (Co_{0.90}Fe_{0.05}Cr_{0.05})₇₅ | 33 | 0.5 | 66 | 20 | 25 | Rectangle |
| | (Si_{0.5}B_{0.5})₂₅ | | | | | | |
| Example 8 | (Co_{0.90}Fe_{0.05}Cr_{0.05})₇₅ | 33 | 0.2 | 165 | 20 | 10 | Rectangle |
| | (Si_{0.5}B_{0.5})₂₅ | | | | | | |
| Example 9 | Co_{0.68}Fe_{0.04}Cr_{0.02}Si_{0.14} | 50 | 0.2 | 250 | 18 | 11 | Rectangle |
| | B_{0.11}Nb_{0.01} | | | | | | |
| Example 10 | Co_{0.68}Fe_{0.04}Si_{0.155} | 50 | 0.2 | 250 | 18 | 11 | Rectangle |
| | B_{0.12}Nb_{0.005} | | | | | | |
| Comparative | (Fe_{0.90}Co_{0.10})₈₀ | 10 | 0.03 | 333 | 30 | 1 | Circle |
| example 1 | (Si_{0.5}B_{0.5})₂₀ | | | | | | |
| Comparative | (Fe_{0.90}Co_{0.10})₈₀ | 33 | 0.2 | 165 | 20 | 10 | Rectangle |
| example 2 | (Si_{0.5}B_{0.5})₂₅ | | | | | | |
| Comparative | (Co_{0.90}Fe_{0.05}Cr_{0.05})₇₅ | 3 | 0.01 | 300 | 6 | 17 | Semi- |
| example 3 | (Si_{0.5}B_{0.5})₂₅ | | | | | | ellipse |
| Comparative | (Co_{0.90}Fe_{0.05}Cr_{0.05})₇₅ | 2 | 0.2 | 10 | 20 | 10 | Rectangle |
| example 4 | (Si_{0.5}B_{0.5})₂₅ | | | | | | |

Next, as listed in Table 2 (which will be described later), pieces of security paper were made as examples 1A to 10A. Those pieces of security paper in the examples 1A to 10A each include the corresponding magnetic thin strips of the examples 1 to 10 in the Table 1. Moreover, pieces of comparative security paper were made as comparative examples 1A to 4A listed in the Table 2. Those pieces of comparative security paper in the comparative examples 1A to 4A each include the corresponding magnetic thin strips of the comparative examples 1 to 4 in the Table 1.

Specifically, two pieces of A4 size paper (297 mm in length×210 mm in width) were prepared. The magnetic thin strips were arranged on one of the two pieces of paper. The other piece of paper was attached to the former to form one piece of paper (A4 size). The numbers of magnetic thin strips are each shown in Table 2. The pieces of security paper were made by the process described above. In the same manner as described above, the pieces of comparative security paper were made by arranging the comparative magnetic thin strips on two pieces of paper.

The insulation layer made of a parylene resin was provided as needed. The number of the magnetic thin strips is the number per an A4 size. The paper (the paper body 4) having a brightness equal to or larger than 85% was used. As for the arrangement of the magnetic thin strips and the comparative magnetic thin strips, they were randomly arranged when the number of them is equal to or larger than 20, and they were radially arranged from the center of the paper or in a similar manner when the number of them is smaller than 20.

TABLE 2

| | | | The number | Done or not |
|---|---|---|---|---|
| | Magnetic | Insulation | of magnetic | done of random |
| | sensor | treatment | thin strips | arrangement |
| Example 1A | Example 1 | Not done | 4 | Done (radially) |
| Example 1B | Example 1 | Done | 20 | Done |
| Example 1C | Example 1 | Not done | 100 | Done |
| Example 1D | Example 1 | Not done | 1 | Not done |
| Example 2A | Example 2 | Not done | 3 | Done (radially) |
| Example 2B | Example 2 | Not done | 10 | Done (radially) |
| Example 3A | Example 3 | Not done | 10 | Done (radially) |
| Example 4A | Example 4 | Not done | 5 | Done (radially) |
| Example 5A | Example 5 | Not done | 2000 | Done |
| Example 6A | Example 6 | Not done | 30 | Done |
| Example 6B | Example 6 | Not done | 300 | Done |
| Example 7A | Example 7 | Not done | 10 | Done (radially) |
| Example 8A | Example 8 | Not done | 20 | Done |
| Example 9A | Example 9 | Not done | 10 | Done (radially) |
| Example 10A | Example 10 | Not done | 10 | Done (radially) |
| Comparative | Comparative | Not done | 2000 | Done |
| example 1A | example 1 | | | |
| Comparative | Comparative | Not done | 4 | Done (radially) |
| example 2A | example 2 | | | |
| Comparative | Comparative | Not done | 300 | Done |
| example 3A | example 3 | | | |
| Comparative | Comparative | Not done | 2000 | Done |
| example 4A | example 4 | | | |

In Table 2, “done” in the done or not done of random arrangement column means that at least some of the magnetic thin strips or the comparative magnetic thin strips were arranged such that their length directions L differed from each other. In Table 2, “done (radially)” in the done or not done of random arrangement column means that at least some groups in the magnetic thin strips or the comparative magnetic thin strips included in the paper were radially arranged.

On the pieces of security paper of examples 1A to 10A, a presence or absence of overlapping of the magnetic thin strips, a presence or absence of a hole, the brightness, and a bending property were measured.

For the measurement of the presence or absence of overlapping of the magnetic thin strips, the presence or absence of a part where the magnetic thin strips overlapped with each other was checked in the security paper. It was also checked whether a hole was made in the security paper when a circle was drawn using an HB pencil. When the circle was drawn using the pencil, the security paper was used as drawing line paper in a handwriting density test in compliance with JIS-S-6006 of Japanese Industrial Standards (JIS).

The brightness was measured in compliance with the foregoing JIS-P-8148. Specifically, the method (ISO brightness R₄₅₇) was performed in which a reflected light amount was digitized when a security paper surface was irradiated with light.

The bending property was measured in such a manner to check a presence or absence of the damage of the magnetic thin strip or the security paper when being bent 180° at the area where the magnetic thin strips lie. The 180° bending was performed such that the paper was bent 180° in one direction, and thereafter the paper was bent 180° in the opposite direction. After the bending, the presence or absence of the damage was checked. The damage refers to a state that cracking occurred at least part of the magnetic thin strip or the security paper, or a state that at least part of the magnetic thin strip or the security paper was separated.

In the same manner as the examples 1A to 10A, the presence or absence of overlapping of the magnetic thin strips, the presence or absence of a hole, the brightness, and the bending property were measured on the pieces of comparative security paper of the comparative examples 1A to 4A.

The measurement results are listed in Table 3 below.

TABLE 3

| | Presence or | Presence or | | Presence or |
|---|---|---|---|---|
| | absence of | absence of | | absence of |
| | overlapping | hole made | Bright- | damages in |
| | of magnetic | by pencil | ness | bending property |
| | sensors | drawing | (%) | measurement |
| Example 1A | Absent | Absent | 85 | Absent |
| Example 1B | Absent | Absent | 85 | Absent |
| Example 1C | Absent | Absent | 85 | Absent |
| Example 1D | Absent | Absent | 85 | Absent |
| Example 2A | Absent | Absent | 85 | Absent |
| Example 2B | Absent | Absent | 85 | Absent |
| Example 3A | Absent | Absent | 85 | Absent |
| Example 4A | Absent | Absent | 85 | Absent |
| Example 5A | Absent | Absent | 82 | Absent |
| Example 6A | Absent | Absent | 85 | Absent |
| Example 6B | Absent | Absent | 85 | Absent |
| Example 7A | Absent | Absent | 85 | Present |
| Example 8A | Absent | Absent | 85 | Present |
| Example 9A | Absent | Absent | 85 | Absent |
| Example 10A | Absent | Absent | 85 | Absent |
| Comparative | Present | Present | 80 | Present |
| example 1A | | | | |
| Comparative | Absent | Absent | 85 | Absent |
| example 2A | | | | |
| Comparative | Present | Present | 82 | Present |
| example 3A | | | | |
| Comparative | Absent | Absent | 81 | Present |
| example 4A | | | | |

The pieces of security paper of the comparative examples 1A to 10A had no overlapping of the magnetic thin strips. As a result, defects such as a hole opened in the paper did not occur after the pencil drawing. In contrast, overlapping of the comparative magnetic thin strips was found in each of the security papers of the comparative examples 1A and 3A. As described above, the comparative example 1A includes the comparative magnetic thin strips having a circular cross section in the comparative example 1 of Table 1, and the comparative example 3A includes the comparative magnetic thin strips having a semi-elliptic cross section in the comparative example 3 of the Table 1. The paper flatness deteriorates at the portion where the relative magnetic thin strips overlapped. As a result, a hole was made in the comparative security paper of each of comparative examples 1A and 3A after the pencil drawing.

Moreover, in the examples 1A to 10A, the security paper whose number of the magnetic thin strips was equal to or smaller than 50 kept the brightness 85%. In other words, the original brightness of the paper was kept without any change. In the examples 1A to 10A, the security paper whose number of the magnetic thin strips was larger than 50 deteriorated in brightness.

The security paper of each of the examples 1A to 6B was not damaged as to the bending property. The security paper of the example 7A had a damaged portion. This damage is due to a change in strength of the kickback caused by a difference in the direction of cutting the long magnetic thin strip. In other words, the cutting is preferably performed such that the width of the long magnetic thin strip becomes the length L of the magnetic thin strip. The damage was also found in the comparative security paper of the comparative examples 1A, 3A, and 4A. This is due to the strong kick back caused by that the cross-sectional shape of the comparative magnetic thin strips was a circler or a semi-elliptic, and that the length L was relatively short. The security paper of the example 8A was damaged when being bent 180° because the security paper included the magnetic thin strips after having been subjected to the heat treatment. This makes it understandable that the heat treatment is preferably not performed when bending is needed.

Next, the coercive force and the reception sensitivity were measured on the pieces of security paper of the examples 1A to 10A and the pieces of comparative security paper of the comparative examples 1A to 4A.

The coercive force (A/m) was measured under conditions that the frequency was 10 kHz and the applied magnetic field was 80 A/m.

The reception sensitivity was measured using the theft prevention gates as the management system. Specifically, the reception sensitivity was measured using the management system 6 illustrated in FIG. 7. As described above with reference to FIG. 7, the management system 6 includes the gate 7 performing transmission and the gate 8 performing reception. The gate 7 as the transmission side and the gate 8 as the reception side have the same size. The gates 7 and 8 each have a width W of 326 mm, a depth D of 80 mm, and a height H of 1670 mm. The distance between the gates 7 and 8 was 1.5 m.

A sine wave having a frequency of 1.04 kHz was used for an operation signal, which is an alternating magnetic field applied to the gate 7 serving as the transmission side. The reception sensitivity was measured when each of the pieces of security paper and the pieces of comparative security paper was passing through between the gates 7 and 8. The reception sensitivity is expressed by a relative value to a value of 1 on the assumption that the magnitude of a reception signal is 1 when the comparative security paper of the comparative example 1A is used. The larger the value of the reception sensitivity was, the larger the received signal was. The reception side obtains the signal of sine waves corresponding to the signal on the excitation side. When the magnetic body passes through between the sides, a pulse current occurs. The peak value of this pulse current was read.

The measurement results are listed in the following Table 4.

TABLE 4

| | Coercive | Reception | Pulse |
|---|---|---|---|
| | force (A/m) | sensitivity | current (mA) |
| Example 1A | 22 | 1.8 | 116 |
| Example 1B | 22 | 1.8 | 120 |
| Example 1C | 22 | 1.8 | 124 |
| Example 1D | 22 | 1.4 | 34 |
| Example 2A | 22 | 2.0 | 167 |
| Example 2B | 22 | 2.0 | 168 |
| Example 3A | 22 | 1.8 | 135 |
| Example 4A | 22 | 2.0 | 164 |
| Example 5A | 22 | 1.8 | 118 |
| Example 6A | 22 | 1.5 | 68 |
| Example 6B | 22 | 1.7 | 101 |
| Example 7A | 22 | 1.5 | 58 |
| Example 8A | 10 | 2.2 | 187 |
| Example 9A | 22 | 2.0 | 165 |
| Example 10A | 22 | 2.0 | 168 |
| Comparative | 38 | 1.0 | 2 |
| example 1A | | | |
| Comparative | 38 | 1.1 | 3 |
| example 2A | | | |
| Comparative | 22 | 1.3 | 18 |
| example 3A | | | |
| Comparative | 22 | 1.3 | 18 |
| example 4A | | | |

As illustrated in the Table 4, the coercive force of the security paper of each of the examples 1A to 10A using the magnetic thin strips of the embodiment was low. The lower the coercive force is, the more quickly the state returns to a non-magnetized sate. The low coercive force allows the sensor to be turned on and off quickly.

Moreover, the pieces of security paper of the examples 1A to 10A had higher reception sensitivities than those of the pieces of comparative security paper of the comparative examples 1A to 4A. It is understandable from comparison between examples 1A, 1B, and 1C that, the sufficient number of the magnetic thin strips included in the security paper is equal to or larger than 50 when the length L of the magnetic thin strip is equal to or larger than 25 mm. The reception sensitivity of the example 1D, in which the number of the magnetic thin strips is one, was lower than those of the examples 1A to 1C.

It is understandable from comparison between the examples 6A and 6B that, the reception sensitivity can be enhanced by setting the number of the magnetic thin strips to be equal to or larger than 50 when the length L of the magnetic thin strip is smaller than 25 mm.

The reception sensitivity of the security paper of the example 8A was higher than those of the other examples and the comparative examples 1A to 4A. The heat treatment is effective for enhancing magnetic properties. Therefore, the heat treatment is preferably performed depending on whether the security paper needs to have the bending property.

In the case that the Fe-based amorphous alloy is used for the comparative magnetic thin strips, such as the comparative examples 1A and 2A shown in the Table 1, the reception sensitivities was lower than those of the examples in which the Co-based amorphous alloy was used. Although the Co-based amorphous alloy was used like the comparative examples 3A and 4A, the reception sensitivities were lowered because the sizes of the comparative magnetic thin strips differed from those of the magnetic thin strips.

As described above, the security paper, which is paper including the magnetic thin strips according to the embodiment, is able to prevent the overlapping of the magnetic thin strips. In addition, the brightness can be kept, thereby preventing the original color of paper from being changed. The good bending property made handling property well. The reception sensitivity was excellent. The reliability of the management system can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A Co-based amorphous magnetic thin strip for a magnetic sensor, comprising:
a Co-based amorphous magnetic thin strip having
a width W equal to or smaller than 1 mm,
a length L between 6 mm and 100 mm inclusive,
a ratio L/W between 20 and 1000 inclusive,
a strip thickness t between 10 μm and 28 μm inclusive, and
a cross section of a rectangle or a trapezoid.

2. The Co-based amorphous magnetic thin strip according to claim 1, wherein the Co-based amorphous magnetic thin strip has a ratio W/t between 3 and 20 inclusive.

3. The Co-based amorphous magnetic thin strip according to claim 1, wherein the Co-based amorphous magnetic thin strip is not damaged even when being bent 180°.

4. The Co-based amorphous magnetic thin strip according to claim 1, further comprising an insulation layer provided on a surface of the Co-based amorphous magnetic thin strip.

5. A magnetic sensor comprising:
an object including one or more Co-based amorphous magnetic thin strips, each being the Co-based amorphous magnetic thin strip according to claim 1.

6. The magnetic sensor according to claim 5, wherein the object is a piece of paper.

7. The magnetic sensor according to claim 6, wherein a number of the Co-based amorphous magnetic thin strips per paper area of 62370 mm² corresponding to an A4 size is between 3 and 2500 inclusive.

8. The magnetic sensor according to claim 5, wherein the Co-based amorphous magnetic thin strips do not overlap with each other.

9. The magnetic sensor according to claim 6, wherein a number of the Co-based amorphous magnetic thin strips per paper area of 62370 mm² corresponding to an A4 size is equal to or smaller than 50 when the length L of each of the Co-based amorphous magnetic thin strip is equal to or larger than 25 mm.

10. The magnetic sensor according to claim 6, wherein a number of the Co-based amorphous magnetic thin strips per paper area of 62370 mm² corresponding to an A4 size is larger than 50 when the length L of each of the Co-based amorphous magnetic thin strip is smaller than 25 mm.

11. The magnetic sensor according to claim 5, further comprising an insulation layer provided on a surface of each of the one or more Co-based amorphous magnetic thin strips,
wherein each of the one or more Co-based amorphous magnetic thin strips has a ratio W/t between 3 and 20 inclusive.

12. The magnetic sensor according to claim 11, wherein the object is a piece of paper.

13. The magnetic sensor according to claim 12, wherein a number of the Co-based amorphous magnetic thin strips per paper area of 62370 mm² corresponding to an A4 size is between 3 and 2500 inclusive.

14. A management system comprising:
the magnet sensor according to claim 5.

15. The management system according to claim 14, further comprising a pair of gates that transmit and receive radio waves between one another.
